(19) United States
(12) Patent Application Publication
(10) Pub. No.: US 2014/0145797 A1
(43) Pub. Date: May 29, 2014

(54) COMMON MODE NOISE CHIP FILTER AND METHOD FOR MANUFACTURING THE SAME

(71) Applicant: SAMSUNG ELECTRO-MECHANICS CO., LTD., Suwon-si (KR)

(72) Inventors: Jun Hee BAE, Suwon-si (KR); Sang Moon LEE, Suwon-si (KR); Sung Kwon WI, Suwon-si (KR); Yong Suk KIM, Suwon-si (KR)

(73) Assignee: SAMSUNG ELECTRO-MECHANICS CO., LTD., Suwon-si (KR)

(21) Appl. No.: 13/842,789

(22) Filed: Mar. 15, 2013

(30) Foreign Application Priority Data
Nov. 29, 2012 (KR) 10-2012-0137050

(51) Int. Cl. H03H 7/01

(52) U.S. Cl. CPC H03H 7/0138; H03H 3/00
USPC 333/185; 29/600

(57) ABSTRACT

Disclosed herein are a common mode noise chip filter and a method for manufacturing the same, the common mode noise chip filter including: a ferrite substrate; coil patterns formed on the ferrite substrate; and a ferrite-polymer complex layer formed on the result substrate having the coil patterns formed therein, wherein the ferrite-polymer complex layer has a multilayer structure, so that the ferrite-polymer complex layer filling an inner space of the substrate having inner coil patterns is formed to have the multilayer structure but not a single-layer structure, thereby lowering internal stress, and thus improving reliability of the common mode noise chip filter as a product.

### CROSS REFERENCE(S) TO RELATED APPLICATIONS

This application claims the benefit under 35 U.S.C. Section 119 of Korean Patent Application Serial No. 10-2012-0137050, entitled “Common Mode Noise Chip Filter and Method for Manufacturing the Same” filed on Nov. 29, 2012, which is hereby incorporated by reference in its entirety into this application.

### BACKGROUND OF THE INVENTION

1. Technical Field

The present invention relates to a common mode noise chip filter and a method for manufacturing the same.

2. Description of the Related Art

Electronic devices in our environment are sources of radiation noise, to a greater or lesser degree. Since the noise is freely transformed and appears briefly and then vanishes as described above, there is a need for measures to prevent the electronic device itself from being a source of noise and resistance (immunity) measures to prevent occurrence of malfunction due to even foreign noise. This is a fundamental thought of EMC.

Generally, conduction noise is allowed to ‘by-pass’ to a ground through a condenser or ‘absorbed’ to a resistor, a ferrite core, a chip bead, or the like, to be transformed into heat, and then removed.

In addition to above method, another method is for countering conductive noise. According to this method, noise current is ‘reflect’ed by using property of an inductor. The inductor allows direct current to flow well therethrough, but the inductor has high impedance (resistance against alternating current) and thus alternating current does not flow well through the inductor. Meanwhile, there are two types, a differential mode and a common mode as the transfer type of conduction noise, and thus noise prevention measures depending on the difference therebetween are needed. Even though parts for noise prevention measures are added to a circuit, noise is rather increased without confirming the type of noise.

The common mode is a conduction mode that flows in the same direction with respect to a forward route and a return route. Common mode noise may be generated due to non-parallel impedance of a wiring system or the like, and may be more remarkable in higher frequencies. In addition, since the common mode noise is transferred to the ground or the like and returned while drawing a large loop, it causes several noise interferences in even electronic devices far away.

Therefore, in the digital devices, common mode noise measures become at least as important as differential mode noise measures.

As shown in FIG. 1, a common mode noise filter has a structure in which an insulating layer 12 is formed on a ferrite substrate 11; a resist insulating layer 14 for forming internal coil conductors 13 is formed; the coil conductors 13 are connected by via electrodes (not shown); and the coil conductors 13 are connected to external electrodes 16 by lead-out lines 15 on an outer peripheral surface of the substrate 11.

In addition, an opening (not shown) is formed inside the coil conductors 13 to pass through the resist insulating layer 14, and a ferrite-polymer complex layer 18 fills an inside of the opening.

A top view of the structure of FIG. 1 is shown in FIG. 2.

The ferrite-polymer complex layer 18 of the related art has a structure including a single layer ferrite complex layer formed by filling once, as shown in FIG. 3. The ferrite-polymer complex layer 18 is composed of a polymer resin 19 and a ferrite powder 20.

A ferrite powder used in order to increase permeability is mixed with a resin to prepare a slurry, and then the slurry fills the substrate. However, as shown in FIG. 3, when the ferrite complex layer is formed by filing the cavity with a single layer, an inside of the substrate may be easily damaged due to internal stress caused by electrical impact or mechanical impact. In addition, at the time of manufacturing and mounting a chip, cracks may occur due to deficiency in adhesive strength with the polymer binder, which is caused by thermal impact.

### RELATED ART DOCUMENT

### Patent Document

(Patent Document 1) Japanese Patent Laid-Open Publication No. 2010-283289

### SUMMARY OF THE INVENTION

An object of the present invention is to provide a common mode noise chip filter having excellent reliability by changing a structure of a ferrite complex layer used to improve permeability, which is an index of noise suppression effect, and thus lowering internal stress.

Another object of the present invention is to provide a method for manufacturing the common mode noise chip filter having the above characteristics.

According to an exemplary embodiment of the present invention, there is provided a common mode noise chip filter, including: a ferrite substrate; coil patterns formed on the ferrite substrate; and a ferrite-polymer complex layer formed on the result substrate having the coil patterns formed therein, wherein the ferrite-polymer complex layer has a multilayer structure.

Here, one layer in the ferrite-polymer complex layer may have a thickness of 5˜20 μm.

The ferrite-polymer complex layer may have a total thickness of 80˜150 μm.

Here, a ferrite powder of the ferrite-polymer complex layer may be a Ni—Zn—Cu based ferrite powder.

Here, a ferrite powder of the ferrite-polymer complex layer may have a particle size of 1˜50 μm.

Here, a ferrite powder of the ferrite-polymer complex layer may be at least one of a spherical powder, a flake powder, and a mixture powder thereof.

Here, a polymer of the ferrite-polymer complex layer may be at least one selected from the group consisting of an epoxy resin, a polyimide resin, a polyamide resin, and a polyaniline resin.

Here, a polymer of the ferrite-polymer complex layer may be an epoxy resin.

The epoxy resin may have viscosity of 1˜5 cps.

Here, a ferrite powder and a polymer of the ferrite-polymer complex layer may be mixed at a weight ratio of 7:1˜10:1.

The ferrite-polymer complex layer may further include a solvent and a dispersant.

According to another exemplary embodiment of the present invention, there is provided a method for manufacturing a common mode noise chip filter, the method including: forming coil patterns on a ferrite substrate; filling the resultant substrate having the coil patterns therein with a ferrite dispersion liquid; evaporating a solvent in the ferrite dispersion liquid; injecting a polymer into a ferrite from which the solvent is evaporated, to form a ferrite-polymer complex layer; and repeating the filling of the resultant substrate, the evaporating of the solvent, and the injecting of the polymer to form a multilayer-structure ferrite-polymer complex layer.

The ferrite dispersion liquid may include a ferrite powder, the solvent, and a dispersant.

The ferrite powder and the solvent may be included at a weight ratio of 4:1˜8:1.

The dispersant may be included in a content within 10 wt % of the whole dispersion liquid.

The polymer may be at least one selected from the group consisting of an epoxy resin, a polyimide resin, a polyamide resin, and a polyaniline resin.

The polymer may be an epoxy resin.

The epoxy resin may have viscosity of 1˜5 cps.

### BRIEF DESCRIPTION OF THE DRAWINGS

FIG. 1 is a cross-sectional view of a common mode noise chip filter according to the related art;

FIG. 2 is a top view of FIG. 1;

FIG. 3 is a cross-sectional view of a common mode noise chip filter including a single layer ferrite-polymer complex layer according to the related art;

FIG. 4 is a cross-sectional view of a common mode noise chip filter according to one exemplary embodiment of the present invention;

FIGS. 5 and 6 are internal pictures of conventional common mode noise chip filters manufactured by Comparative Example 1 after a lead heat-resistance test; and

FIGS. 7 and 8 are internal pictures of common mode noise chip filters manufactured by Examples 1 and 2 after a lead heat-resistance test.

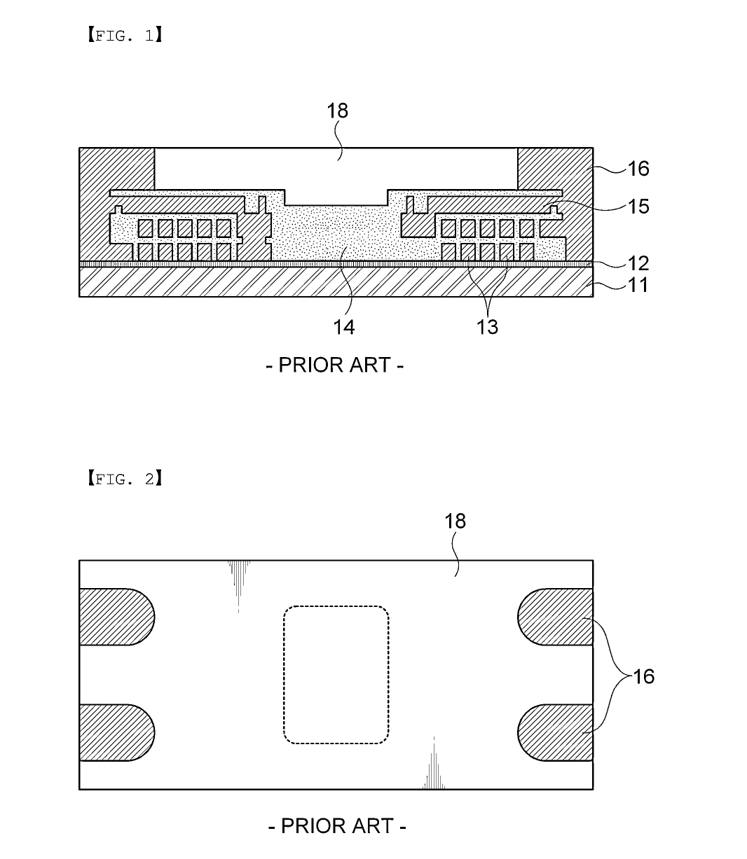

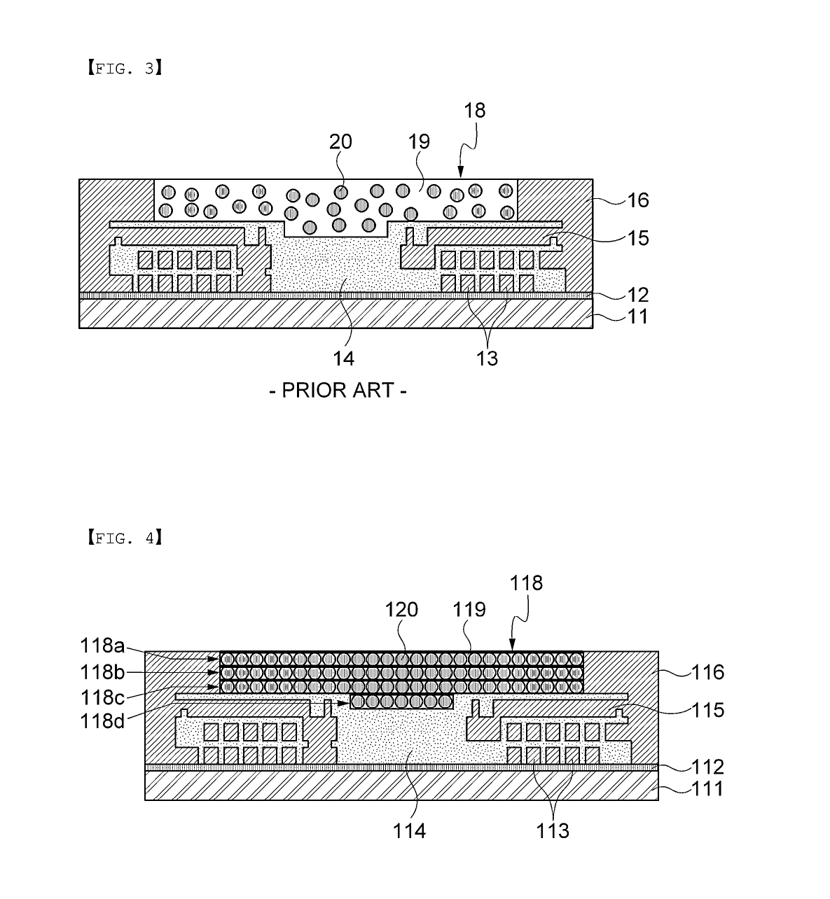

### DESCRIPTION OF THE PREFERRED EMBODIMENTS

Hereinafter, the present invention will be described in more detail with reference to the accompanying drawings.

Terms used in the present specification are for explaining the embodiments rather than limiting the present invention. As used herein, unless explicitly described to the contrary, a singular form includes a plural form in the present specification. Also, used herein, the word “comprise” and/or “comprising” will be understood to imply the inclusion of stated constituents, steps, operations and/or elements but not the exclusion of any other constituents, steps, operations and/or elements.

The present invention is directed to a common mode noise chip filter and a method for manufacturing the same.

A common mode noise chip filter according to an exemplary embodiment of the present invention is characterized by forming a ferrite-polymer complex layer to have a multilayer structure but not in a single-layer structure.

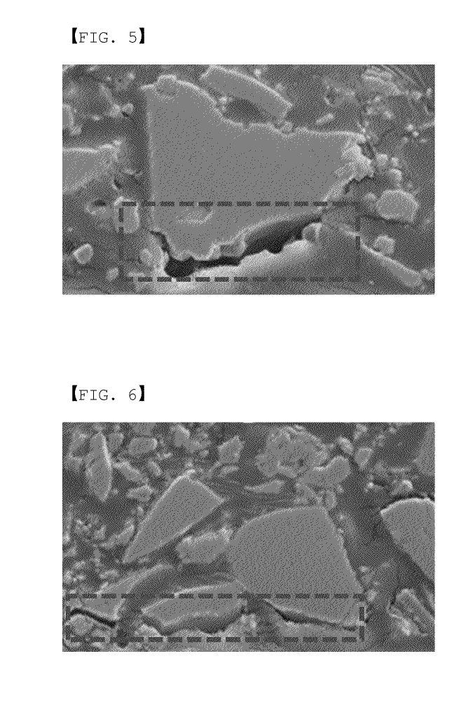

Referring to FIG. 4 showing a structure of the common mode noise chip filter according to the exemplary embodiment of the present invention, the commode mode noise chip filter includes a ferrite substrate 111, coil patterns 113 formed above the ferrite substrate 111, and a ferrite-polymer complex layer 118 formed above the resultant substrate having the coil patterns 113 formed therein. The ferrite-polymer complex layer 118 is characterized by having a multilayer structure.

In addition, an insulating layer 112 for allowing insulation between the ferrite substrate 111 and the coil patterns 113 and a resist insulating layer 114 for forming the coil patterns 113 are included in the ferrite substrate 111.

The coil patterns 113 are connected by via electrodes (not shown), and then are connected with external electrodes 116 formed on an outer peripheral surface of the ferrite substrate 111 by lead-out lines 115.

Conventionally, the ferrite-polymer complex layer has been formed to have a predetermined thickness requested for the ferrite-polymer complex layer by filling once, as shown in FIG. 3. However, in this case, reliability may be deteriorated, such as cracks easily occur due to external impact. Therefore, in the present invention, the ferrite-polymer complex layer 118 is formed to have a multilayer structure but not a single layer structure, so that internal stress of the chip filter is lowered, resulting in excellent mechanical and electrical properties against external impact.

According to the present invention, in the ferrite-polymer complex layer 118, one layer may have a thickness in the range of 5˜20 μm. In addition, a total thickness of the ferrite-polymer complex layer 118 according to the present invention may be 80˜150 μm.

Therefore, one layer in the ferrite-polymer complex layer 118 is allowed to have a thickness of 5˜20 μm, and then filling is repeated to reach the total thickness of the ferrite-polymer complex layer 118, thereby forming a multilayer structure of ferrite-polymer complex layer 118. FIG. 4 shows that the ferrite-polymer complex layer 118 has four layers 118a to 118d, but this merely exemplifies that the ferrite-polymer complex layer 118 of the present invention has a multilayer structured, and the present invention is not particularly limited thereto.

A ferrite powder of the ferrite-polymer complex layer 118 is preferably Ni—Zn—Cu based ferrite powder, and optionally may further include at least one selected from the group consisting of Co, Bi, and Ti.

Preferably, the ferrite powder of the ferrite-polymer complex layer may have a particle size of 1˜50 μm. If the size thereof is below 1 μm, dispersibility may be deteriorated. If the size thereof is above 50 μm, the ferrite powder may be easily detached at the time of processing complex materials.

In addition, as the ferrite powder of the ferrite-polymer complex layer according to the present invention, at least one selected from a spherical powder, a flake powder, and a mixture powder thereof may be used. In addition, two or more kinds of spherical powders having different particle sizes may be mixed or two or more kinds of flake powders having different particle sizes may be mixed, but the combination thereof is not particularly limited.

The polymer used in the ferrite-polymer complex layer of the present invention may be at least one selected from an epoxy resin, a polyimide resin, a polyamide resin, and a polyaniline resin. Of these, the epoxy resin may be preferably used.

In the case where the polymer of the ferrite-polymer complex layer is the epoxy resin, viscosity thereof is preferably 1-5 cps. The reason is that, when the ferrite-polymer complex layer of the present invention is formed to have multiple layers, a dispersion liquid in which the ferrite powder is mixed with a solvent and a dispersant is first injected; the solvent is vaporized; and a polymer is later injected among the ferrite powder particles, and thus the polymer needs to be maintained at relatively low viscosity. Therefore, if the viscosity of the epoxy resin is above 5 cps, the epoxy resin may not penetrate into a ferrite layer due to high viscosity thereof.

In the ferrite-polymer complex layer, it is preferable to mix ferrite and polymer at a weight ratio of 7:1˜10:1 in view of dispersibility and processability.

The ferrite-polymer complex layer may further include a solvent and a dispersant. The solvent and the dispersant are not particularly limited, and those that can be used in a general ferrite-polymer complex layer may be used.

Meanwhile, a general ferrite substrate may be used as the ferrite substrate 111 used in the common mode noise chip filter of the present invention, and a material of the ferrite is not particularly.

A plurality of insulating layers 112 are formed on the ferrite substrate 111, and the coil patterns 113 are formed on the respective insulating layers 112. The coil patterns 113 of the respective insulating layers 112 are connected to each other by neighboring via electrodes (not shown), and the resist insulating layers 114 for forming the coil patterns 113 are formed.

The insulating layers 112 serve to insulate the respective coil patterns 113 from each other and secure flatness of the surfaces on which the internal electrode coil patterns 113 are formed. A polymer resin having excellent electrical and magnetic insulating characteristics and good processability may be preferably used as a material for the insulating layer 112. Examples thereof may be an epoxy resin, a polyimide resin, and the like, but the present invention is not particularly limited thereto.

In addition, the internal electrode coil patterns 113 according to the present invention may be formed by using copper (Cu), aluminum (Al), or the like, having excellent conductivity and processability. The internal electrode coil patterns 113 may be formed by using an etching method using photolithography or an additive method (plating method), but the method thereof is not particularly limited.

An opening is formed inside of the respective internal electrode coil patterns 113, which corresponds to a center of each of the insulating layers 112 while the opening penetrates the insulating layers 112. The internal electrode coil patterns 113 formed on each of the insulating layers 112 are electrically connected to each other by via electrodes in each layer. In addition, respective ends of the internal electrode coil patterns 113 are connected to the external electrode terminals 116 through the lead out lines 115. Generally, four external electrode terminals 116 are formed at both lateral surfaces of the outer peripheral surface.

This common mode noise chip filter of the present invention may be manufactured by a first step of forming internal coil patterns on a ferrite substrate; a second step of filling the resultant substrate having the internal coil patterns therein with a ferrite dispersion liquid; a third step of evaporating a solvent in the ferrite dispersion liquid; a fourth step of injecting a polymer into a ferrite from which the solvent is evaporated, to form a ferrite-polymer complex layer; and a fifth step of repeating the second to fourth steps to form a multilayer-structure ferrite-polymer complex layer.

At the first step, the internal electrode coil patterns are formed on a general ferrite substrate. The internal electrode coil pattern may be formed by using copper (Cu) or aluminum (Al) having excellent conductivity and processability.

At the second step, the ferrite dispersion liquid fills an opening inside the resultant substrate having the internal electrode coil patterns formed therein.

The ferrite dispersion liquid used herein may include a ferrite powder, a solvent, and a dispersant. The ferrite powder is preferably a Ni—Zn—Cu based powder having a particle size of 1˜50 μm, and a spherical powder, a flake powder, and a mixture powder thereof may be used. In addition, two or more kinds of ferrite powders having different particle sizes and shapes may be used by mixture, and any combination that can raise dispersibility and filling density may be used.

The ferrite dispersion liquid may include the ferrite powder and the solvent at a weight ratio of 4:1˜8:1 therein, and dispersibility is the greatest in the above range. As the solvent, any solvent that can be used in the ferrite-polymer complex layer may be used.

In addition, there are BYK2155, BYK102, BYK103, and the like, as a dispersant in the ferrite dispersion liquid, but the present invention is not limited thereto. It is preferable to include the dispersant in a concentration of 10 wt % or less in the whole dispersion liquid in view of securing optimal dispersibility and improving permeability.

At a third stage, a solvent in the ferrite dispersion liquid is evaporated. A method for evaporating the solvent is not particularly limited.

At a fourth step, a polymer resin 119 is injected among the ferrite powder particles 120 from which the solvent is completely evaporated, to form a ferrite-polymer complex layer 118 as shown in FIG. 4. Here, the injected polymer may be at least one selected from the group consisting of an epoxy resin, a polyimide resin, a polyamide resin, and a polyaniline resin, and of these, the epoxy resin is most preferable.

In the case where the polymer of the present invention is the epoxy resin, viscosity thereof is preferably 1˜5 cps in view of processability since the epoxy resin is easily injected into the ferrite layer.

After the polymer resin is allowed to fill among the ferrite powder particles, the polymer resin is hardened, to form a final ferrite-polymer complex layer. A single layer of the thus ferrite-polymer complex layer may have a thickness of 5˜20 μm.

In addition, the second to fourth steps are repeatedly conducted until the thickness reaches a predetermined value, to thereby allow the ferrite-polymer complex layer 118a to 118d to have a total thickness of about 80˜150 μm. Here, the number of layers is not particularly limited.

Hereinafter, examples of the present invention will be described in detail. The following examples merely illustrate the present invention, but the scope of the present invention should not be construed to be limited by these examples. Further, the following examples are illustrated by using specific compounds, but it is apparent to those skilled in the art that equivalents thereof are used to obtain equal or similar levels of effects.

### Example 1

A ferrite dispersion liquid was prepared by dispersing a spherical ferrite powder (NiZnCu ferrite) having a diameter of 5 μm and a small amount of dispersant (BYK2155) in a solvent (ethanol). The weight ratio of the solvent and the ferrite powder was 10:8. The dispersant was added in a concentration of 2 wt % based on the weight of the ferrite powder.

The ferrite dispersion liquid filled a cavity of the resultant substrate having copper internal electrode coil patterns formed therein. Then, a solvent in the ferrite dispersion liquid was evaporated.

After all the solvent was evaporated, an epoxy resin having low viscosity of 1˜5 cps was injected thereinto by using a micropipette, to form one ferrite-polymer complex layer having a thickness of 5 μm. Then, heat was applied to the ferrite-polymer complex layer, to harden the epoxy resin.

After hardening the epoxy resin, processes of filling with ferrite dispersion liquid, evaporating solvent, injecting epoxy resin thereinto, and hardening were repeated, to form a ferrite-polymer complex layer having a total thickness of 100 μm, in which 20 layers were formed.

Outer terminals of the internal electrode coil patterns were connected to external electrode terminals through drawing terminals (lead-out lines), so that a common mode noise chip filter was manufactured.

### Example 2

A common mode noise chip filter was manufactured by the same procedure as Example 1, except that a flake ferrite powder having a diameter of 20 μm was used and a ferrite-polymer complex layer having five layers of which each has a thickness of 20 μm.

### Comparative Example 1

A common mode noise chip filter was manufactured by the same procedure as Example 1, except that a ferrite-polymer complex layer having a thickness of 100 μm was formed by coating a slurry mixture liquid, in which a ferrite powder and an epoxy resin were mixed at a weight ratio of 9:1, in a cavity of the resultant substrate having copper internal electrode coil patterns formed therein.

### Experimental Example

### Confirmation on Inner Structure after Lead Heat-Resistance Test

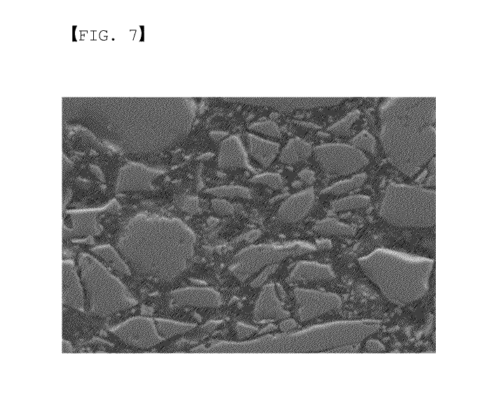

The common mode noise chip filters manufactured according to Examples 1 and 2 and Comparative Example 1 were dipped in a lead (Pb) bath of 300° C. three times for 10 seconds, and then internal structures thereof were confirmed. The confirmation results were shown in FIGS. 5 to 8.

Referring to FIGS. 5 and 6 showing the internal structure of the noise chip filter according to Comparative Example 1, in the case where the ferrite-polymer complex layer was formed to have a single-layer structure like the related art, cracks (square marks) occurred inside the ferrite-polymer composite layer.

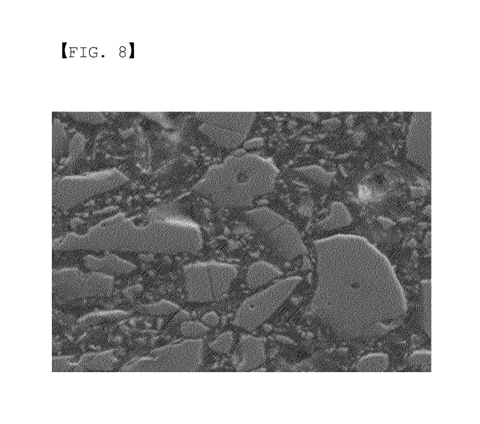

However, referring to FIGS. 7 and 8 showing internal pictures of Examples 1 and 2 in which the ferrite-polymer complex layer was formed to have a multilayer structure like the present invention, it was confirmed that cracks or defects did not occur inside the ferrite-polymer composite layer.

As set forth above, according to the present invention, the ferrite-polymer complex layer filling an inner space of the resultant substrate having the internal coil patterns formed therein is formed in a multilayer structure but not in a single-layer structure, thereby lowering internal stress, so that reliability of the common mode noise chip filter as a product can be improved.

Further, the manufactured common mode noise chip filter can have improved electric strength and mechanical strength.

What is claimed is:

1. A common mode noise chip filter, comprising:
a ferrite substrate;
coil patterns formed on the ferrite substrate; and
a ferrite-polymer complex layer formed on the result substrate having the coil patterns formed therein,
wherein the ferrite-polymer complex layer has a multilayer structure.

2. The common mode noise chip filter according to claim 1, wherein one layer in the ferrite-polymer complex layer has a thickness of 5˜20 μm.

3. The common mode noise chip filter according to claim 1, wherein the ferrite-polymer complex layer has a total thickness of 80˜150 μm.

4. The common mode noise chip filter according to claim 1, wherein a ferrite powder of the ferrite-polymer complex layer is a Ni—Zn—Cu based ferrite powder.

5. The common mode noise chip filter according to claim 1, wherein a ferrite powder of the ferrite-polymer complex layer has a particle size of 1˜50 μm.

6. The common mode noise chip filter according to claim 1, wherein a ferrite powder of the ferrite-polymer complex layer is at least one of a spherical powder, a flake powder, and a mixture powder thereof.

7. The common mode noise chip filter according to claim 1, wherein a polymer of the ferrite-polymer complex layer is at least one selected from the group consisting of an epoxy resin, a polyimide resin, a polyamide resin, and a polyaniline resin.

8. The common mode noise chip filter according to claim 1, wherein a polymer of the ferrite-polymer complex layer is an epoxy resin.

9. The common mode noise chip filter according to claim 8, wherein the epoxy resin has viscosity of 1˜5 cps.

10. The common mode noise chip filter according to claim 1, wherein a ferrite powder and a polymer of the ferrite-polymer complex layer are mixed at a weight ratio of 7:1˜10:1.

11. The common mode noise chip filter according to claim 1, wherein the ferrite-polymer complex layer further includes a solvent and a dispersant.

12. A method for manufacturing a common mode noise chip filter, the method comprising:
forming coil patterns on a ferrite substrate;
filling the resultant substrate having the coil patterns therein with a ferrite dispersion liquid;
evaporating a solvent in the ferrite dispersion liquid;
injecting a polymer into a ferrite from which the solvent is evaporated, to form a ferrite-polymer complex layer; and
repeating the filling of the resultant substrate, the evaporating of the solvent, and the injecting of the polymer, to form a multilayer-structure ferrite-polymer complex layer.

13. The method according to claim 12, wherein the ferrite dispersion liquid includes a ferrite powder, the solvent, and a dispersant.

14. The method according to claim 13, wherein the ferrite powder and the solvent are included at a weight ratio of 4:1˜8:1.

15. The method according to claim 13, wherein the dispersant is included in a content within 10 wt % of the whole dispersion liquid.

16. The method according to claim 12, wherein the polymer is at least one selected from the group consisting of an epoxy resin, a polyimide resin, a polyamide resin, and a polyaniline resin.

17. The method according to claim 12, wherein the polymer is an epoxy resin.

18. The method according to claim 17, wherein the epoxy resin has viscosity of 1˜5 cps.
